(19) United States
(12) Patent Application Publication
(10) Pub. No.: US 2022/0334180 A1
(43) Pub. Date: Oct. 20, 2022

(54) REAL-EQUIVALENT-TIME FLASH ARRAY DIGITIZER OSCILLOSCOPE ARCHITECTURE

(71) Applicant: Tektronix, Inc., Beaverton, OR (US)

(72) Inventors: John J. Pickerd, Hillsboro, OR (US); Kan Tan, Portland, OR (US); Heike Tritschler, Louisville, CO (US); Evan Douglas Smith, Portland, OR (US); Williams Fabricio Flores Yepez, Pittsburgh, PA (US)

(73) Assignee: Tektronix, Inc., Beaverton, OR (US)

(21) Appl. No.: 17/724,393

(22) Filed: Apr. 19, 2022

Related U.S. Application Data
(60) Provisional application No. 63/177,148, filed on Apr. 20, 2021.

(51) Int. Cl. G01R 31/317; G01R 31/319; G06N 20/00

(52) U.S. Cl. CPC G01R 31/31722; G01R 31/31727; G01R 31/31926; G06N 20/00

(57) ABSTRACT

A test and measurement system includes a clock recovery circuit configured to receive a signal from a device under test and to produce a pattern trigger signal, a flash array digitizer having an array of counters having rows and columns configured to store a waveform image representing the signal received from the device under test, a row selection circuit configured to select a row in the array of counters, and a ring counter circuit configured to receive a clock signal, select a column in the array of counters, produce end of row signals, and produce a fill complete signal upon all of the columns having been swept, the fill complete signal indicating completion of the waveform image, an equivalent time sweep logic circuit configured to receive the pattern trigger signal and the end of row signals from the ring counter and to produce the clock signal with a delay to increment a clock delay to the ring counter until the fill complete signal is received, and a machine learning system configured to receive the waveform image and provide operating parameters for the device under test. A test and measurement system includes a flash array digitizer having an array of counters having rows and columns configured to store a waveform image representing a signal received from a device under test, a row selection circuit configured to select a row in the array of counters, a column selection circuit configured to select a column in the array of counters, a sample clock connected to the row selection circuit and the column selection circuit, and a machine learning system configured to receive the waveform image from the flash array digitizer and provide operating parameters for the device under test.

### CROSS-REFERENCE TO RELATED APPLICATIONS

This application claims the benefit of U.S. Provisional Pat. App. No. 63/177,148, filed Apr. 20, 2021, the entire contents of which are hereby incorporated by reference into this disclosure.

### TECHNICAL FIELD

This disclosure relates to test and measurement instruments, and more particularly to oscilloscopes.

### BACKGROUND

Large data centers employ millions of optical transceivers in switches and routers. These transceivers undergo tuning on the manufacturing line as part of the testing prior to sale. The manufacturer optical transmitter tuning can take up to 2 hours. This typically involves sweeping the tuning parameters and measuring Transmitter and Dispersion Eye Closure Quaternary (TDECQ). This may result in anywhere from 3-5 iterations to 200 iterations of the tuning process. Taking this long to tune and test optical transmitters represents a bottleneck in production and increases costs.

As the measurement process becomes more efficient, the bottleneck becomes the acquisition time of the scope. Therefore, the acquisition time becomes a significant limiting factor in the measurement throughput, and increasing throughput will improve the production.

### BRIEF DESCRIPTION OF THE DRAWINGS

FIG. 1 show a representation of an equipment stack using a real-equivalent-time flash array digitizer.

FIG. 2 shows a schematic of a test and measurement system.

FIG. 3 shows a diagram of one embodiment of a flash array digitizer.

FIGS. 4-6 show diagrams of alternative embodiments of a real equivalent time flash array digitizer (RETFAD™).

FIGS. 7-8 show diagrams of embodiments of an X-Y real equivalent time flash array digitizer.

### DESCRIPTION

Embodiments of the disclosure include an integrated oscilloscope or other test and measurement device employing a real equivalent time flash array digitizer (RETFAD™). This architecture may apply to many different areas in electronics. In one area, the embodiments may speed up the tuning of optical transceivers on the manufacturing line.

Embodiments also include a neural network, also referred to as a machine learning system, to process waveform image outputs from the flash array digitizer and associate that image with a set of optical transceiver tuning parameters. The embodiments include configurations that do not incorporate a standard A/D converter. The flash array digitizer does not create binary representations of the waveform. Instead, it increments counters in an array that represent voltage and position of the sample to create an image of the waveform. Embodiments may incorporate both a standard A/D converter and a flash converter for high-speed waveform image capture, and for standard YT (Y-axis v. time) waveform acquisition. In both cases, the scope operates in equivalent time (ET) mode only.

The embodiments of the device architecture referred to as RETFAD′ may apply in many different areas in electronics fields. One particular application is to speed up the tuning of optical transmitters on the manufacturing line. Switch suppliers buy the transmitters and then qualify them for interoperability for use in large data centers that have millions of transceivers installed. This means the interface to the customer's optical transceiver control and tuning software becoming an integral part of the system. The software has the responsibility of controlling the optical transmitter and setting up tuning parameters into it and then reading back the next estimate for the parameters from the machine learning system.

This architecture operates in ET (equivalent time) mode only just as a standard sampling scope does. Oscilloscopes typically operate in one of three different time scales. First, the scope may operate in real time (RT), in which the scope captures an entire waveform in one pass capturing multiple samples per one cycle. Second, the scope may operate in equivalent time (ET) in which the scope captures one sample per trigger event. Third, the scope may operate in real-equivalent time (RET), which generally captures the waveform at a sample rate lower than the real-time scope and higher than the equivalent time scope, and uses software clock recovery to reconstruct the signal without using a hardware trigger or acquiring the sample at the higher acquisition rate.

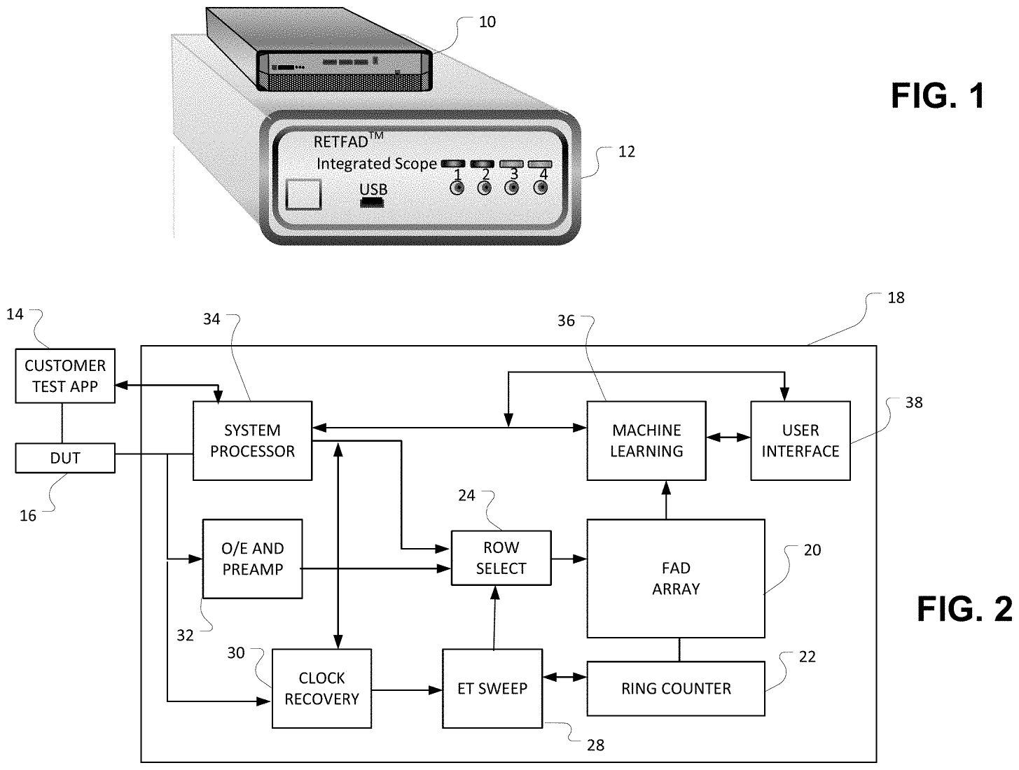

FIG. 1 shows an embodiment of an equipment stack using an oscilloscope having an integrated RETFAD′. The stack may include a computing device 10 that operates a customer software application that performs testing on the optical transceivers. One should note that while this discussion focuses on optical transceivers, other types of devices under test (DUT) could use this process. The second device 12 comprises an integrated oscilloscope or other test and measurement device that may include a hardware clock recovery circuit, the RETFAD′ circuits and the test and measurement device. Alternatively, the hardware pattern trigger clock recovery module may comprises a separate device.

FIG. 2 shows an overall schematic of an embodiment of a test and measurement system that includes the RETFAD′ circuitry. The system has several components, some or all of which may reside in the integrated test and measurement device. These will be discussed in more detail in further diagrams, with FIG. 2 providing an overall system view. The system shows a customer application 14 that may run on the computing device 10 and may also contain the machine learning system, or may operate on a different computing device. The system operates to tune and test DUTs 16, such as optical transceivers. The test and measurement system 18 may also send signals to, and receive signals from, those DUTs. A machine learning system 36 may be incorporated on an internal computing device or a device other than one that operates the user's testing application.

The test and measurement system includes the flash array digitizer array 20 that comprises an array of logic elements, such as counters, organized in rows and columns. As the DUT undergoes testing, it generates a signal. The signal may undergo optical to electrical conversion and/or some preamplification through one or more circuits shown as a block 32. The system may include one or more optical to electrical converters 32. One can implement the RETFAD™ without these converters. The use of the converter 32 depends upon the nature of the DUT.

A clock recovery circuit 30 also uses the signal from the DUT to recover the clock signal and may include hardware typically included in a sampling oscilloscope, as well as hardware pattern trigger that provides a trigger pulse for each instance of a repeating waveform data pattern. As will be discussed in more detail later, this acts as the reference time point that synchronizes equivalent time (ET) sweep logic and the ring counter to the incoming waveform. The sample clock comes from the test and measurement device and determines the base real-time sample rate. This clock controls a track and hold sample time with respect to the pattern trigger. It also controls the increments of the ring counter connected to the FAD array to clock a counter to record a sample. The clock recovery circuit will also include a phase-locked loop to synchronize the edge of the sample clock to time align with the pattern trigger position.

In one embodiment, the system may includes real-equivalent-time (RET) software clock recovery operating on one or more processors such as 34, making the clock recovery hardware optional, or selectable between the two options of software clock recovery and hardware clock recovery.

The system further includes what this discussion refers to as the row select circuitry 24. In order to act as a waveform memory, the system needs to selected a row and a column in the array in which to store the waveform data. As will be discussed in more detail in later figures, the row selection circuitry may comprise a flash converter, or an analog-to-digital converter (A/D). The ring counter 22 selects the columns. As mentioned above, the ring counter selects which column of counters in the array increments with each successive clock. The ring counter provides an end of row signal. The ring counter comprises one continuous chain of flip-flops but the system treats it as if it has a number of rows, in this case L. As the array receives clocks and waveform data, it captures every Lth sample of a waveform. For example, if the sample rate is 100 GigaSamples/sec, and they are clocked in at 10 GigaSamples/sec, the array would capture every tenth sample in the array each sweep. The first sweep would start at the first counter, the offset then causes the second sweep to start at the second counter, etc., until 10 sweeps complete, ‘filling in’ the other samples.

The equivalent time (ET) sweep logic 28 comprises hardware logic devices that receive the pattern trigger output from the clock recovery hardware, and the end of row signals from the ring counter. In response, the ET logic increments the sweep clock signal delay with respect to the pattern trigger reference position, using a track and hold circuit discussed in more detail later. It takes L triggers to fill in a length of the input waveform equal to the width of the FAD array. This would fill in two unit interval (UI) intervals of the input waveform with respect to the pattern trigger. When the ET sweep logic receives each ring counter end of row signal, then the offset will step to the next sample after the first two UI intervals. The offsets for each end of row signal will be equal to one sample interval of the final ET sample rate. All sample intervals of the repeating pattern having a record length N will be filled with equivalent time samples.

Once the counters in the array have captured all the samples, the resulting waveform image comprises an image of signal amplitude (Y-axis) over time, or a YT image. The array transfers this image to a machine learning system 36. The machine learning system, having been previously trained to associate waveform images with particular tuning parameters, then produces a signal back to the test application that includes the operational parameters for the DUT. Those parameters then allow the test application to tune the DUT with those parameters and perform a pass/fail test on the DUT. This provides a much faster method of tuning and testing DUTs than manually and respectively setting, testing and adjusting the parameters for the DUTs to see if they pass or fail. The system may also include a user interface 38, which may comprise a display, and/or controls that allow the user to interact with the system such as a keyboard, buttons, knobs, or mouse as examples. The user interface may provide a selection for different components of the system, discussed in more detail further.

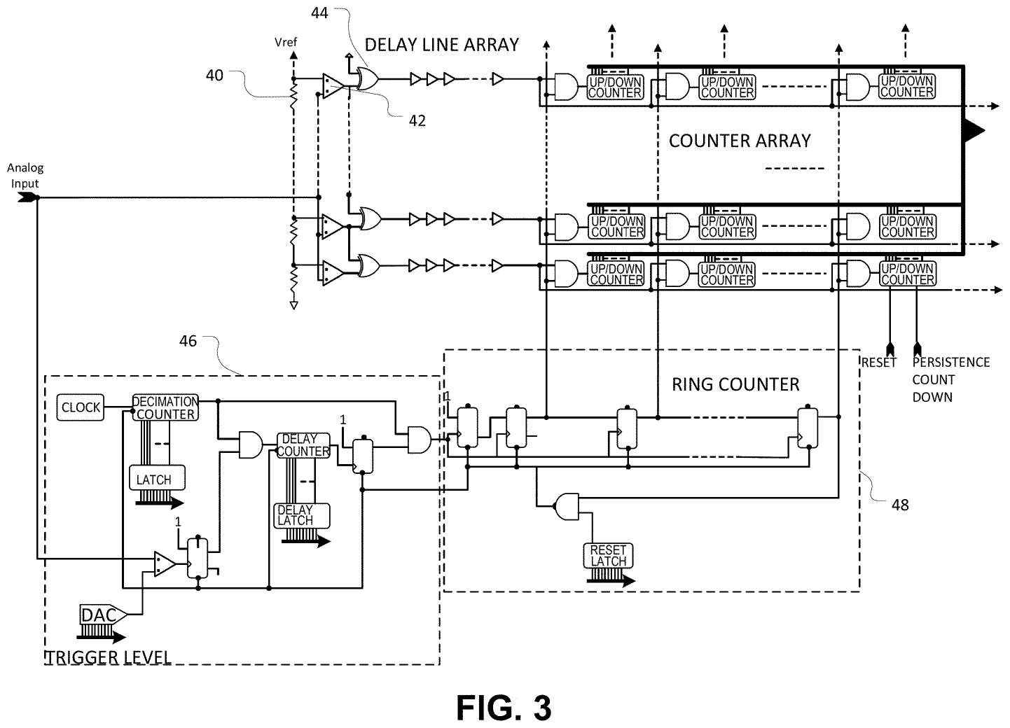

A main component of this system is the flash array digitizer (FAD) and the FAD array of counters. These operate as described in U.S. Pat. No. 7,098,839, hereinafter “Pickerd,” which is incorporated herein by reference in its entirety. FIG. 3 shows a more detailed view of the array of counters and the selection circuitry. The FAD has resistors such as 40 arranged in series between a voltage reference and a group point to form a voltage divider. The voltage divider divides the reference voltage into N reference signal portions, where N is the number of rows in the array of counters. Each reference signal portion is applied to the non-inverting input of a corresponding comparator such as 42 while the analog signal from the DUT is applied to the inverting input of the comparators. Each comparator provides a positive output when the voltage level of the waveform exceeds the reference signal for that comparator. The output of each comparator connects to an input of a corresponding logic device 44, and each successive logic device connects to the output of the corresponding comparator, and an input of the previous logic device. This connection pattern continues for all the logic devices. The second input of the first logic device is connected to a low or zero logic level. Each logic device may be an XOR gate.

Each logic device such as 44 provides its output signal to the counter array, either directly or through one or more delay line elements. The sweep mechanism 48, a ring counter as discussed above, operates to select a column of the array at a given instance. At the given instance one counter in the array that has both inputs to a logic element, such as an AND gate attached to it, go high, which results in selection of that counter. That counter either increments or decrements. The counter array essentially stores a YT image of the waveform, which may be thought of as a waveform database, as discussed in U.S. Pat. Nos. 7,216,046 and 5,343,405, each of which are incorporated by reference herein in their entirety.

The FAD directly maps the samples into the waveform image without ever converting the samples into a binary format, as discussed in Pickerd. One should note that the trigger mechanism 46 disclosed in Pickerd may operate differently than the clock recovery and pattern trigger hardware discussed with the embodiments here.

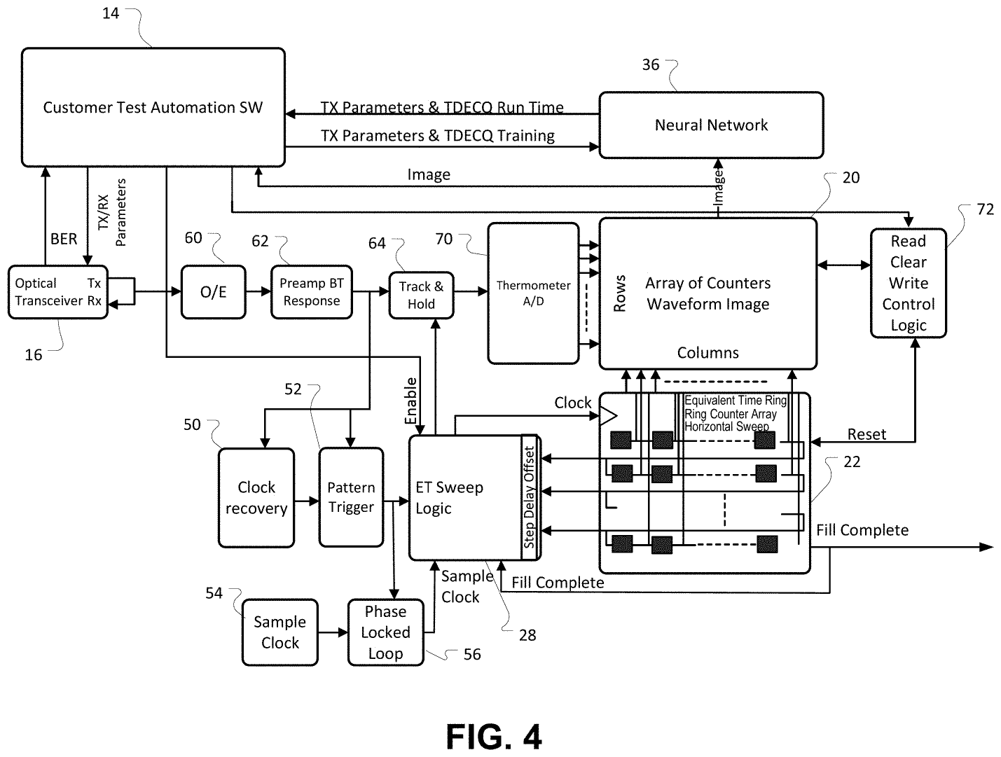

FIGS. 4-6 show embodiments of the RETFAD™ to create a YT image for the machine learning system to provide the operational parameters for the tuning process. In FIG. 4, the customer test automation software application 14 sends the transmit and receive parameters, i.e. tuning parameters, to the device under test 16, which is an optical transceiver. The DUT, operating with those parameters then generates an output signal, typically a waveform. The block 32 from FIG. 1 in this embodiment takes the form of an optical to electrical converter 60 that converts the output signal into an electrical signal which undergoes preamplification and, optionally filtering by a hardware Bessel Thomson (BT) filter to provide a constant group/phase delay at 62. The preamplifier provides the output signal to the clock recovery hardware 50, and the pattern trigger 52. These are in turn provided to the phase locked loop 56 with the sample clock 54, to produce the sample clock used by the ET sweep logic 28, as discussed above. The ET sweep logic provides the clock signals to the ring counter 22 and the track and hold circuit 64.

As discussed above, the ring counter 22 sweeps the columns of the counter array 20 to select the columns successively for storing samples of the waveform data. In this embodiment, the row selection circuitry comprises a thermometer analog-to-digital converter (A/D) 70, rather than a standard A/D. The thermometer A/D, which may be referred to as a flash array converter, may comprise a voltage divider with a stack of comparators, similar to that discussed above. The thermometer A/D, upon receiving the signal from the track and hold circuit 62, produces an output thermometer code. The thermometer code then feeds into a series of XOR gates such as those shown in FIG. 3 that in turn select one of the rows of the counter array.

This embodiment also includes read and write control logic 72 configured to transfer the waveform image data to the machine learning system 36. This logic may also operate to clear and reset all of the counters in the array after the transfer is complete.

The machine learning system/neural network 36 will undergo training under control of the customer test automation software using data sets comprised of YT waveform images (or Fast Fourier Transforms of the YT image, other waveform images, including XY images, etc.), and the associated operating parameters, to allow it to receive waveform images and provide associated operating parameters to tune the optical transceiver. After training, the system will move into run time, where it will provide the operating parameters to the customer test automation software to allow that software to tune the transceivers for testing.

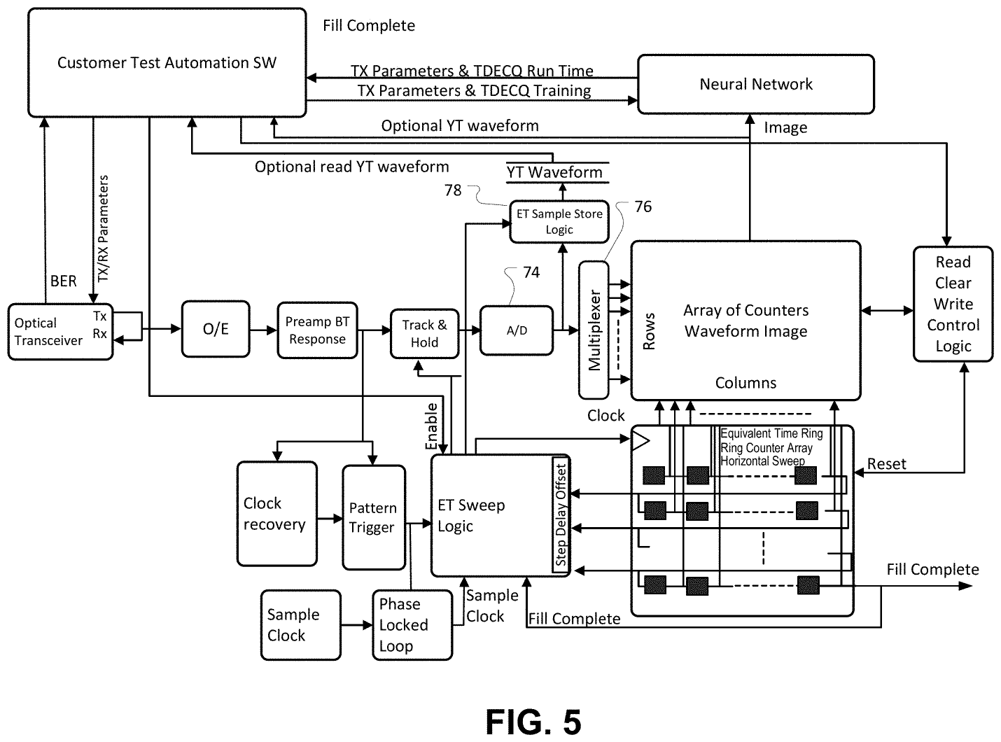

The embodiment of FIG. 5 shows many of the same components as FIG. 4, but the row selection circuit comprises a “standard” A/D 74 instead of the thermometer A/D. This may provide some advantages or different sampling intervals. For example, for an A/D running at 3.125 Gigasamples/second, the number of ET sweeps, or “bins” could be set at 64 to obtain a final sample rate of 200 Gigasamples/sec. This provides one example and many others are of course possible. A multiplexer/demultiplexer 76 would convert the binary output sample into a row selection to the array of counters. The A/D 74 would also provide the YT waveform to the customer test automation software, using a sample and store logic block 78 under timing control of the ET sweep logic to create the complete waveform prior to sending.

In FIGS. 4 and 5, the counter array, sweep logic, ring counter, and reset circuitry may be implemented into a field programmable gate array (FPGA). The FPGA may include other blocks. These embodiments output only a waveform image into a neural network trained by the customer to estimate tuning parameters for their optical transceiver. This version does not have the ability to apply filters to the acquired waveform. The array does not convert samples to binary numbers at the sample rate determined by the RT sample clock. Post-acquisition filters may not be needed because the neural network shall be trained to associate the waveform image as is, with a set of tuning parameters in the transceiver. The machine learning system may be trained on unfiltered waveforms from the flash array digitizer array or from filtered waveforms from real-equivalent-time (RET) software, discussed below.

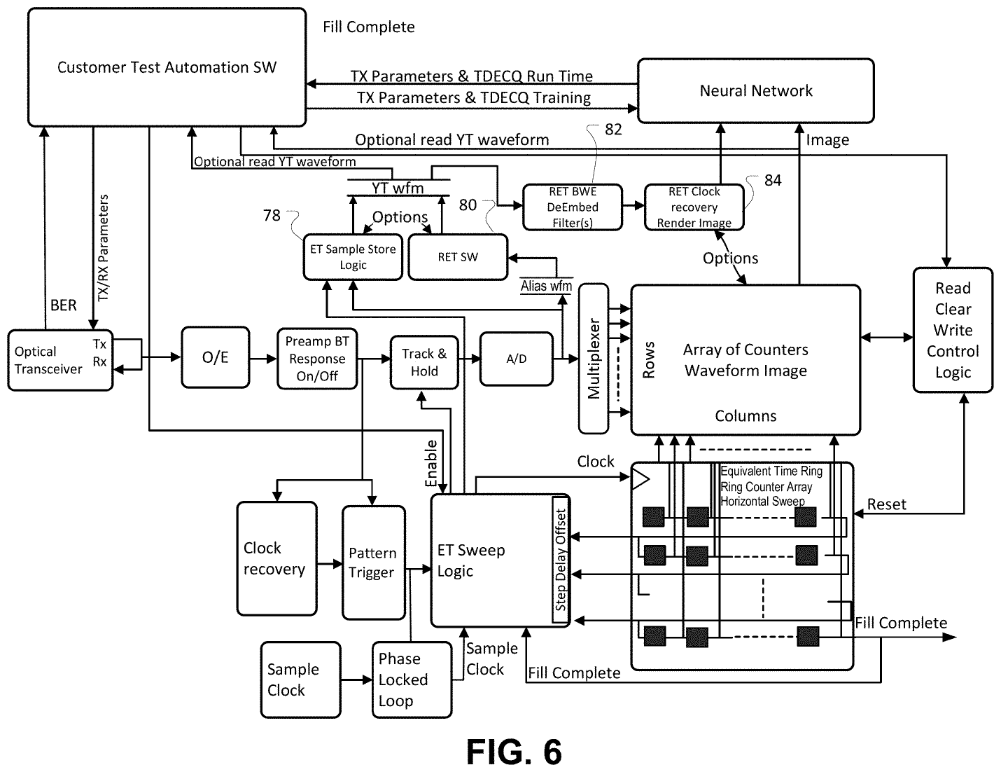

FIG. 6 shows an embodiment having multiple options selectable by the customer automation software through a user interface, or set by the test operator. This embodiment may include the clock recovery hardware such as the clock recovery block, pattern trigger block, etc. as discussed above, and/or software clock recovery, referred to here as RET software 80. The RET software may execute code on one or more processors that cause the one or more processors to perform a software clock recovery. This process is discussed in detail in U.S. patent application Ser. No. 17/183,056, “REAL-EQUIVALENT-TIME OSCILLOSCOPE,” published as U.S. Pat. App. Pub. No. 20210263085 (the '056 application), which is hereby incorporated by reference in its entirety. In the RET approach, the one or more processors execute code to determine the frequency of the signal and reconstruct from the signal based on that frequency, the signal pattern length and/or the sample rate. This discussion refers to using the RET software for clock recovery and rendering of the waveform image as “RET mode.”

When rendering a waveform image in RET mode, filters may be applied to the YT waveform at 82. If filters are applied prior to rendering a waveform image it will require extra overhead for clock recovery and waveform image rendering at 84. If the FAD mode builds the waveform image, then no filters are applied for that waveform image. However, if the neural net is trained without filters then this should be a good option for some applications such as optical TX tuning parameters.

The RET mode may operate with or without hardware clock recovery, depending upon the user preferences. The software clock recovery may be more accurate than the hardware based recovery at higher frequencies, but using the FAD acquisition may operate faster and require less computing time.

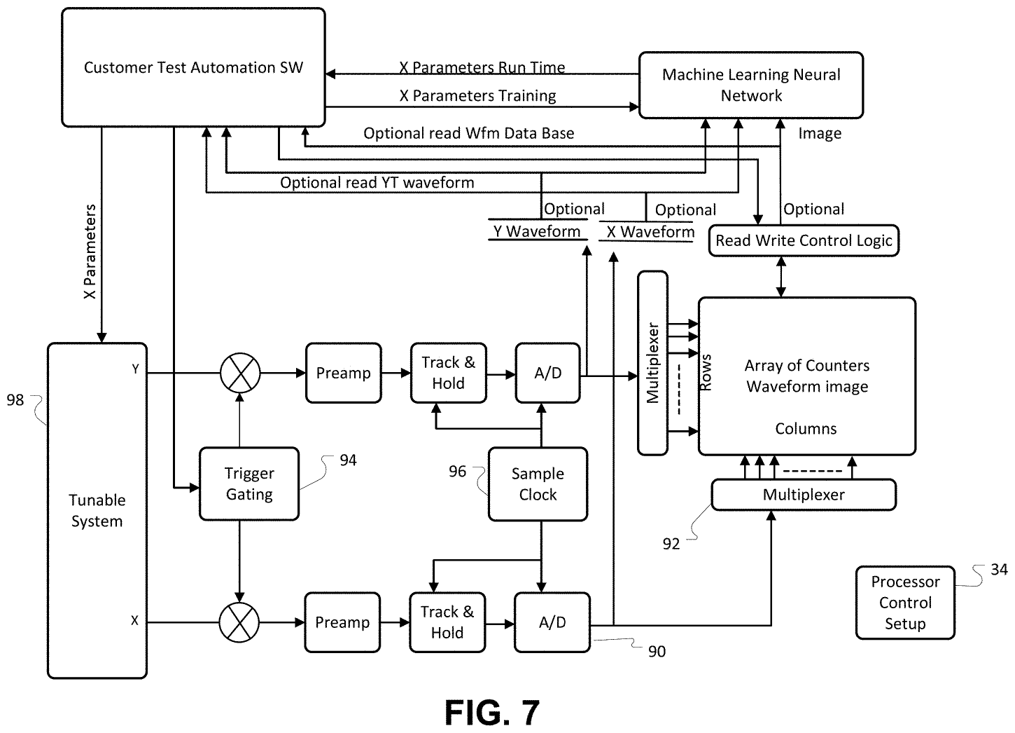

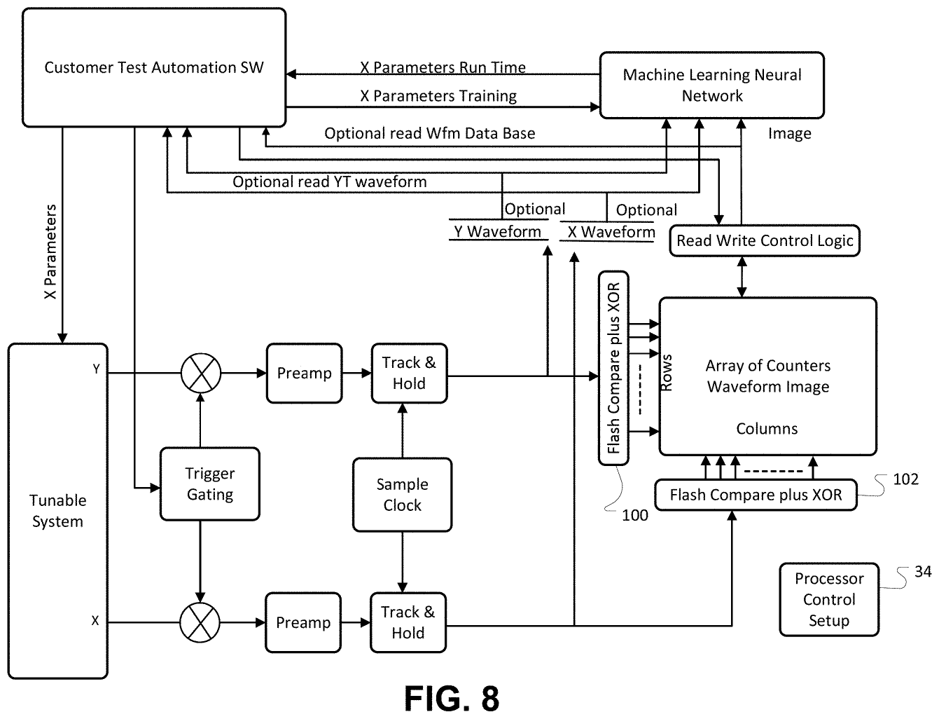

FIGS. 7-8 show embodiments where the system produces an XY image rather than a YT image. In this embodiment, a second A/D 90 and demultiplexer 92 replace the horizontal sweep ring counter, as shown in FIG. 7. This may be applied towards any application where there is a need to display the XY data. The trigger gating 94 and the sample clock 96 replace the hardware or software clock recovery. The preamplification, and track and hold would occur in both the X and Y paths. In these embodiments, the DUT 98 may comprise any type of tunable system or component.

An XY FAD would render more samples/sec into the XY plot, which may then speed up the neural network associations. The embodiments above of the basic FAD would not allow for digital signal processing on the incoming signal. However, machine learning applications where the associations of the XY plot with other data such as tuning parameters may be made without such digital signal processing. This may provide a good way to speed up the neural network training and run time operation.

For example, if both the X and Y channels had IQ data, the XY FAD may allow aliased XY plotting to fill in the desired view, over many acquisitions. In addition, that view may be useful without additional digital signal processing for use in the machine learning algorithms deployed for various purposes. A high bandwidth front end on a low sample rate A/D converter could offer more bits of resolution, lower power, and lower cost than a full bandwidth high performance scope. At the same time, it could allow for much faster data point acquisition than a sampling scope can offer.

FIG. 8 shows another alternative for the XY FAD that does not use the standard A/D converter. This version keeps the track and hold circuits in the X and Y paths, but it uses a flash converter similar to FIG. 4, an array of comparators 100 and 102 that output thermometer code followed by XOR gates to select an individual row and an individual column in the array of counters.

Both XY FAD configurations are well suited for implementation in FPGA logic. This logic will require lower sample rate entry into the XY display. However, for this mode of operation the incoming waveform can be aliased, with low sample rate, and still produce a desired view in the XY view. This makes it desirable for input into machine learning algorithm for some applications.

One should note that the processor 34 may comprise one or more processors, and may function in a distributed manner between a computing device running the computer test automation software, a processor in the test and measurement device, and other processors that may reside in the system.

The RETFAD™ is a combination of real equivalent time sampling and a flash array digitizer. It has advantages of lower cost hardware and lower power consumption than an RT scope with similar bandwidth and sample rate. This is because it works in ET mode only and it directly acquires the waveform into a counter array that represents a waveform image diagram. The version that has a standard A/D converter, also builds the YT waveform in equivalent time. Therefore, it acquires thousands of times faster than a sampling scope, and it does clock recovery and a waveform diagram faster than an RET only scope. The full options to it include RET operation for de-embedding and other filtering, plus clock recovery, plus image render in software, eliminating need for the hardware clock recovery. It also allows for the use of hardware clock recovery in RET mode only, without the FAD waveform image rendering.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

### EXAMPLES

Illustrative examples of the disclosed technologies are provided below. An embodiment of the technologies may include one or more, and any combination of, the examples described below.

Example 1 is a test and measurement system, comprising: a clock recovery circuit configured to receive a signal from a device under test and to produce a pattern trigger signal; a flash array digitizer comprising: an array of counters having rows and columns configured to store a waveform image representing the signal received from the device under test; a row selection circuit configured to select a row in the array of counters; and a ring counter circuit configured to receive a clock signal, select a column in the array of counters, produce end of row signals, and produce a fill complete signal upon all of the columns having been swept, the fill complete signal indicating completion of the waveform image; an equivalent time sweep logic circuit configured to receive the pattern trigger signal and the end of row signals from the ring counter and to produce the clock signal with a delay to increment a clock delay to the ring counter until the fill complete signal is received; and a machine learning system configured to receive the waveform image and provide operating parameters for the device under test.

Example 2 is the test and measurement system of Example 1 wherein the row selection circuit comprises a flash converter comprising: a voltage divider circuit and a stack of comparators to output a thermometer code; a series of logic gates configured to receive the thermometer code and produce a row selection signal to select a row in the array of counters.

Example 3 is the test and measurement system of either of Examples 1 or 2, wherein the row selection circuit comprises an analog-to-digital converter and a multiplexer.

Example 4 is the test and measurement system of Example 1, further comprising a user interface, wherein the user interface is configured to provide a selection to designate either a flash converter or an analog-to-digital converter and a multiplexer as the row selector.

Example 5 is the test and measurement system of any of Examples 1 through 4, wherein the clock recovery circuit comprises a hardware clock recovery circuit.

Example 6 is the test and measurement system of any of Examples 1 through 5, further comprising one or more processors configured to execute code that causes the one or more processors to perform software clock recovery.

Example 7 is the test and measurement system of Example 6, wherein the one or more processors are further configured to execute code to cause the one or more processors to perform filtering on the image prior to reception of the waveform image

Example 8 is the test and measurement system of any of Examples 1 through 7, further comprising a preamplifier with a track and hold circuit configured to receive the signal from the device under test and send a signal to the row selection circuit.

Example 9 is the test and measurement system of Example 8, wherein the preamplifier includes a Bessel Thomson filter configured to be applied to the signal from the device under test.

Example 10 is the test and measurement system of any of Examples 1 through 9, further comprising an optical to electrical converter.

Example 11 is the test and measurement system of any of Examples 1 through 10, further comprising read and write control logic to provide one or more reset signals to the array of counters to clear the counters

Example 12 is the test and measurement system of any of Examples 1 through 11, wherein the machine learning system is configured to operate on unfiltered waveform data.

Example 13 is the test and measurement system of any of Examples 1 through 10, wherein the machine learning system is configured to operate on filtered waveform data.

Example 14 is a test and measurement system, comprising: a flash array digitizer comprising: an array of counters having rows and columns configured to store a waveform image representing a signal received from a device under test; a row selection circuit configured to select a row in the array of counters; a column selection circuit configured to select a column in the array of counters; a sample clock connected to the row selection circuit and the column selection circuit; and

Example 15 is the test and measurement system of Example 14, wherein the row selection circuit and the column selection circuit comprise analog-to-digital converters.

Example 16 is the test and measurement system of either of Examples 14 or 15, further comprising a preamplifier and a track and hold circuit connected to each of the row selection circuit and the column selection circuit, the track and hold circuit also connected to the sample clock.

Example 17 is test and measurement system of any of Examples 14 through 16, wherein the row selection circuit and the column selection circuit comprise flash array digitizers, each flash array digitizers comprising a voltage divider circuit and a stack of comparators to output a thermometer code, and a series of logic gates configured to receive the thermometer code and produce a row selection signal to select a row in the array of counters.

Example 18 is the test and measurement system of any of Examples 14 through 17, further comprising one or more processors configured to execute code that cause the one or more processors to provide operating parameters to the device under test; generate a trigger gating signal for the row selection circuit and the column selection circuit; and produce the sample clock for the row selection circuit and the column selection circuit

Example 19 is the test and measurement system of any of Examples 14 through 18, wherein the machine learning system is configured to operate on unfiltered waveform image data.

Example 20 is the test and measurement system of any of Examples 14 through 18, wherein the machine learning system is configured to operate on filtered waveform image data.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of the disclosure have been illustrated and described for purposes of illustration, it will be understood that various modifications may be made without departing from the spirit and scope of the disclosure. Accordingly, the disclosure should not be limited except as by the appended claims.

1. A test and measurement system, comprising:
a clock recovery circuit configured to receive a signal from a device under test and to produce a pattern trigger signal;
a flash array digitizer comprising:
an array of counters having rows and columns configured to store a waveform image representing the signal received from the device under test;
a row selection circuit configured to select a row in the array of counters; and
a ring counter circuit configured to receive a clock signal, select a column in the array of counters, produce end of row signals, and produce a fill complete signal upon all of the columns having been swept, the fill complete signal indicating completion of the waveform image;
an equivalent time sweep logic circuit configured to receive the pattern trigger signal and the end of row signals from the ring counter and to produce the clock signal with a delay to increment a clock delay to the ring counter until the fill complete signal is received; and
a machine learning system configured to receive the waveform image and provide operating parameters for the device under test.

2. The test and measurement system as claimed in claim 1, wherein the row selection circuit comprises a flash converter comprising:
a voltage divider circuit and a stack of comparators to output a thermometer code; and
a series of logic gates configured to receive the thermometer code and produce a row selection signal to select a row in the array of counters.

3. The test and measurement system as claimed in claim 1, wherein the row selection circuit comprises an analog-to-digital converter and a multiplexer.

4. The test and measurement system as claimed in claim 1, further comprising a user interface, wherein the user interface is configured to provide a selection to designate either a flash converter or an analog-to-digital converter and a multiplexer as the row selector.

5. The test and measurement system as claimed in claim 1, wherein the clock recovery circuit comprises a hardware clock recovery circuit.

6. The test and measurement system as claimed in claim 1, further comprising one or more processors configured to execute code that causes the one or more processors to perform software clock recovery.

7. The test and measurement system as claimed in claim 6, wherein the one or more processors are further configured to execute code to cause the one or more processors to perform filtering on the image prior to reception of the waveform image.

8. The test and measurement system as claimed in claim 1, further comprising a preamplifier with a track and hold circuit configured to receive the signal from the device under test and send a signal to the row selection circuit.

9. The test and measurement system as claimed in claim 8, wherein the preamplifier includes a Bessel Thomson filter configured to be applied to the signal from the device under test.

10. The test and measurement system as claimed in claim 1, further comprising an optical to electrical converter.

11. The test and measurement system as claimed in claim 1, further comprising read and write control logic to provide one or more reset signals to the array of counters to clear the counters.

12. The test and measurement system as claimed in claim 1, wherein the machine learning system is configured to operate on unfiltered waveform image data.

13. The test and measurement system as claimed in claim 1, wherein the machine learning system is configured to operate on filtered waveform image data.

14. A test and measurement system, comprising:
a flash array digitizer comprising:
an array of counters having rows and columns configured to store a waveform image representing a signal received from a device under test;
a row selection circuit configured to select a row in the array of counters; and
a column selection circuit configured to select a column in the array of counters;
a sample clock connected to the row selection circuit and the column selection circuit; and
a machine learning system configured to receive the waveform image from the flash array digitizer and provide operating parameters for the device under test.

15. The test and measurement system as claimed in claim 14, wherein the row selection circuit and the column selection circuit comprise analog-to-digital converters.

16. The test and measurement system as claimed in claim 14, further comprising a preamplifier and a track and hold circuit connected to each of the row selection circuit and the column selection circuit, the track and hold circuit also connected to the sample clock.

17. The test and measurement system as claimed in claim 14, wherein the row selection circuit and the column selection circuit comprise flash converters, each flash converter comprising a voltage divider circuit and a stack of comparators to output a thermometer code, and a series of logic gates configured to receive the thermometer code and produce a row selection signal to select a row in the array of counters.

18. The test and measurement system as claimed in claim 14, further comprising one or more processors configured to execute code that cause the one or more processors to:
provide operating parameters to the device under test;
generate a trigger gating signal for the row selection circuit and the column selection circuit; and
produce the sample clock for the row selection circuit and the column selection circuit.

19. The test and measurement system as claimed in claim 14, wherein the machine learning system is configured to operate on unfiltered waveform image data.

20. The test and measurement system as claimed in claim 14, wherein the machine learning system is configured to operate on filtered waveform image data.
